(19) United States
(12) Patent Application Publication
(10) Pub. No.: US 2025/0309187 A1
(43) Pub. Date: Oct. 2, 2025

(54) SUBSTRATE PROCESSING METHOD, METHOD OF MANUFACTURING SEMICONDUCTOR DEVICE, PROCESSING APPARATUS AND NON-TRANSITORY COMPUTER-READABLE RECORDING MEDIUM

(71) Applicant: Kokusai Electric Corporation, Tokyo (JP)

(72) Inventors: Kazuhiro YUASA, Toyama-shi (JP); Shuntaro MACHIDA, Tokyo (JP); Tsuyoshi ISHIKAWA, Tokyo (JP); Hiroshi ASHIHARA, Tokyo (JP); Naofumi OHASHI, Toyama-shi (JP)

(73) Assignee: Kokusai Electric Corporation, Tokyo (JP)

(21) Appl. No.: 19/090,854

(22) Filed: Mar. 26, 2025

(30) Foreign Application Priority Data
Mar. 27, 2024 (JP) 2024-051213

(51) Int. Cl. H01L 23/00; C23C 16/52

(52) U.S. Cl. CPC H01L 24/81; C23C 16/52; H01L 2224/81193; H01L 2224/81375; H01L 2224/81395; H01L 2924/37

(57) ABSTRACT

It is possible to suppress occurrence of a void when filling underfill material between a substrate and a semiconductor chip. There is provided a technique that includes: performing at least one among: (a) forming an insulating film on a first surface of a substrate and a first microbump formed on the first surface, wherein the first surface faces a semiconductor chip when the substrate and the semiconductor chip are bonded together; and (b) forming the insulating film on a second surface of the semiconductor chip and a second microbump formed on the second surface, wherein the second surface faces the substrate when the substrate and the semiconductor chip are bonded together.

### CROSS-REFERENCE TO RELATED PATENT APPLICATION

This non-provisional U.S. patent application is based on and claims priority under 35 U.S.C. § 119 of Japanese Patent Application No. 2024-051213, filed on Mar. 27, 2024, in the Japanese Patent Office, the entire contents of which are hereby incorporated by reference.

### BACKGROUND

### 1. Field

The present disclosure relates to a substrate processing method, a method of manufacturing a semiconductor device, a processing apparatus and a non-transitory computer-readable recording medium.

### 2. Related Art

According to some related arts, as a part of a manufacturing process of a semiconductor device, a film may be formed on a substrate by supplying a process gas to the substrate in a process vessel.

However, in a part of the manufacturing process of the semiconductor device, when an underfill material is filled between the substrate and a semiconductor chip, a void may occur.

### SUMMARY

According to the present disclosure, there is provided a technique capable of suppressing an occurrence of a void when an underfill material is filled between a substrate and a semiconductor chip.

According to an embodiment of the present disclosure, there is provided a technique that includes: performing at least one among: (a) forming an insulating film on a first surface of a substrate and a first microbump formed on the first surface, wherein the first surface faces a semiconductor chip when the substrate and the semiconductor chip are bonded together; and (b) forming the insulating film on a second surface of the semiconductor chip and a second microbump formed on the second surface, wherein the second surface faces the substrate when the substrate and the semiconductor chip are bonded together.

### BRIEF DESCRIPTION OF THE DRAWINGS

FIGS. 1A to 1E are diagrams schematically illustrating steps in a manufacturing process of a semiconductor device according to a first embodiment of the present disclosure.

FIG. 2 is a diagram schematically illustrating a configuration of a substrate processing apparatus used in an insulating film forming step according to the first embodiment of the present disclosure.

FIG. 3 is a block diagram schematically illustrating a configuration of a controller and related components of the substrate processing apparatus used in the insulating film forming step according to the first embodiment of the present disclosure.

FIG. 4 is a flow chart schematically illustrating an example of the insulating film forming step according to the first embodiment of the present disclosure.

FIGS. 5A to 5D are diagrams schematically illustrating steps in a manufacturing process of a semiconductor device according to a second embodiment of the present disclosure.

FIGS. 6A to 6D are diagrams schematically illustrating steps in a manufacturing process of a semiconductor device according to a third embodiment of the present disclosure.

FIGS. 7A to 7D are diagrams schematically illustrating steps in a manufacturing process of a semiconductor device according to a fourth embodiment of the present disclosure.

### DETAILED DESCRIPTION

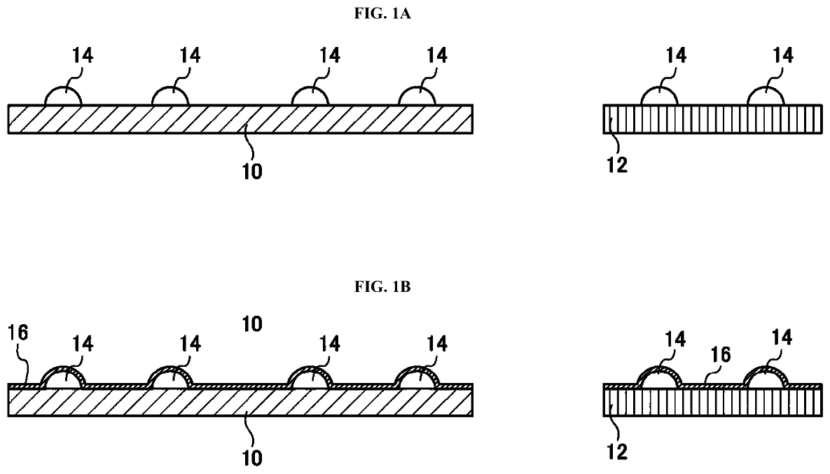

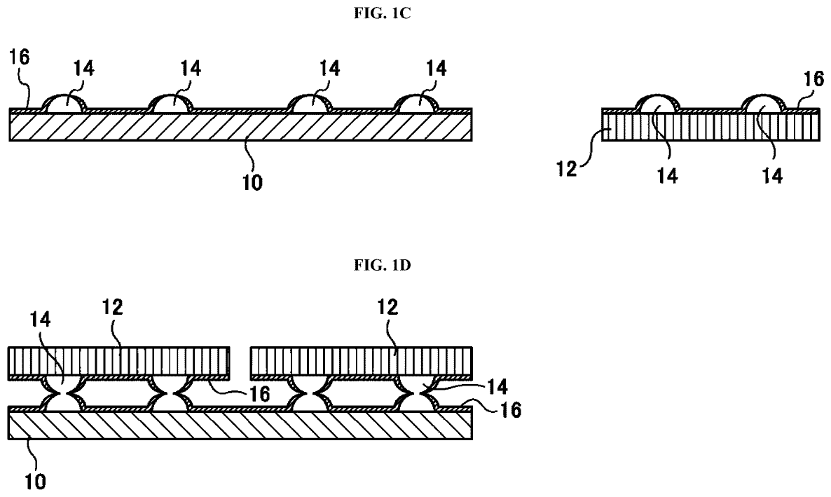

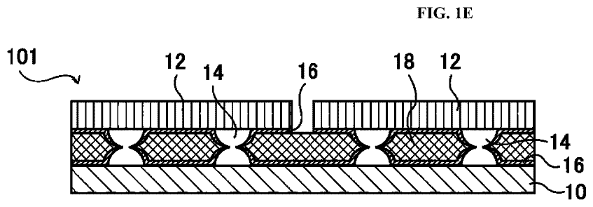

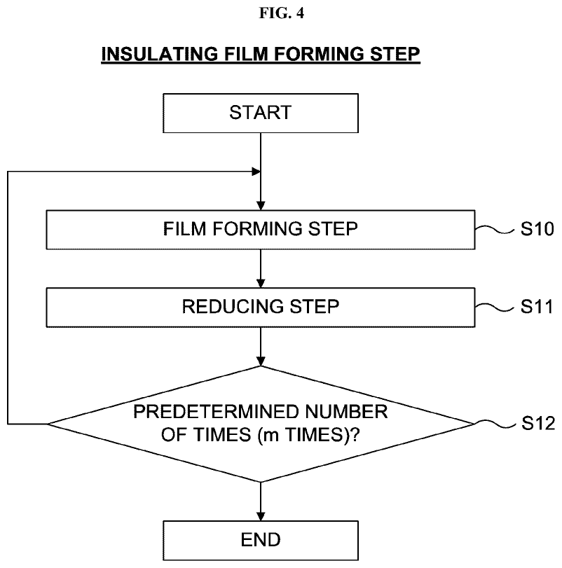

Hereinafter, one or more embodiments (also simply referred to as “embodiments”) according to the technique of the present disclosure will be described mainly with reference to FIGS. 1A to 7D. Further, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, the same or similar reference numerals represent the same or similar components in the drawings. Thus, each component is described with reference to the drawing in which it first appears, and redundant descriptions related thereto will be omitted unless particularly necessary. In addition, the technique of the present disclosure is not limited to the embodiments described below. That is, the technique of the present disclosure may be modified in various ways without departing from the scope thereof. Hereinafter, a first embodiment according to the technique of the present disclosure will be described.

### (1) Manufacturing Process of Semiconductor Device

First, steps in a manufacturing process of a semiconductor device 101 according to the first embodiment of the present disclosure will be described in detail with reference to FIGS. 1A to 1E.

### Microbump Forming Step (Step S1)

As shown in FIG. 1A, a plurality of microbumps 14 are provided (or formed) on a surface of a substrate 10 which is a front surface of the substrate 10 facing a semiconductor chip 12 when the substrate 10 and the semiconductor chip 12 are bonded together (hereinafter, also referred to as the “surface of the substrate 10” or a “first surface”) and on a surface of the semiconductor chip 12 which is a front surface of the semiconductor chip 12 facing the substrate 10 when the substrate 10 and the semiconductor chip 12 are bonded together (hereinafter, also referred to as the “surface of the semiconductor chip 12” or a “second surface”). Hereinafter, each of the plurality of microbumps 14 may also be referred to as a “microbump 14”. In addition, the plurality of microbumps 14 formed on the first surface may also be referred to as “first microbumps 14”, and each of the first microbumps 14 may also be referred to as a “first microbump 14”. Similarly, the plurality of microbumps 14 formed on the second surface may also be referred to as “second microbumps 14”, and each of the second microbumps 14 may also be referred to as a “second microbump 14”. Although not shown, on the surface of the substrate 10 and on the surface of the semiconductor chip 12, a plurality types of films such as an insulating film and a metal film are formed, and a configuration such as an element (device) is also provided. Thus, a material (surface material) of the first surface is different from a material (surface material) of the second surface. On the surface of the substrate 10, the first microbumps 14 are provided at the same intervals as the second microbumps 14 on the surface of the semiconductor chip 12 to be bonded to the substrate 10 and at positions corresponding to those of the second microbumps 14 on the surface of the semiconductor chip 12 to be bonded to the substrate 10. For example, the microbump 14 is made of a material such as a tin (Sn)-containing alloy, a silver (Ag)-containing alloy and a silver tin (AgSn) alloy. As described above, in the present specification, the surface of the substrate 10 (which is the front surface of the substrate 10 facing the semiconductor chip 12 when the substrate 10 and the semiconductor chip 12 are bonded together) may also be referred to as the “first surface”. That is, the first surface includes at least the front surface of the substrate 10. However, the present embodiment is not limited thereto. For example, the first surface may further include at least one among surfaces of the plurality types of films (such as the insulating film and the metal film) and the configuration present on the substrate 10. As described above, in the present specification, the surface of the semiconductor chip 12 (which is the front surface of the semiconductor chip 12 facing the substrate 10 when the substrate 10 and the semiconductor chip 12 are bonded together) may also be referred to as the “second surface”. That is, the second surface includes at least the front surface of the semiconductor chip 12. However, the present embodiment is not limited thereto. For example, the second surface may further include at least one among surfaces of the plurality types of films (such as the insulating film and the metal film) and the configuration present on the semiconductor chip 12.

### Insulating Film Forming Step (Step S2)

Subsequently, as shown in FIG. 1B, for example, by using a substrate processing apparatus 100 described later, an insulating film 16 is formed on the first surface, the second surface and the microbumps 14 (that is, the insulating film 16 is formed on the substrate 10 on which the first microbump 14 is provided and the semiconductor chip 12 on which the second microbump 14 is provided) by a film forming method such as an ALD (Atomic Layer Deposition) method and a CVD (Chemical Vapor Deposition) method. For example, a thickness of the insulating film 16 formed in the present step is set to be 50 nm or less. In addition, the insulating film 16 formed in the present step is a film capable of being formed on a structure (such as the insulating film, the metal film and the microbump 14) present on the surface of the substrate 10 and/or the surface of the semiconductor chip 12.

### Insulating Film Removing Step (Step S3)

Subsequently, as shown in FIG. 1C, the insulating film 16 formed on a top portion (also referred to as an “end portion”) of the first microbump 14 on the surface of the substrate 10 and the insulating film 16 formed on a top portion of the second microbump 14 on the surface of the semiconductor chip 12 are removed to expose the top portions of the microbumps 14 on the surface of the substrate 10 and the surface of the semiconductor chip 12. The top portions of the microbumps 14 on the surface of the substrate 10 and the surface of the semiconductor chip 12 serve as connection surfaces of the microbumps 14 on the surface of the substrate 10 and the surface of the semiconductor chip 12. For example, the insulating film 16 formed on the top portions of the microbumps 14 is removed by a CMP (Chemical Mechanical Polishing) process. However, the present step is not limited to the CMP process. For example, the insulating film 16 formed on the top portions of the microbumps 14 may be removed by a dry etching process. For example, the dry etching process may be performed by forming a photoresist on portions of the microbumps 14 other than the top portions mentioned above and removing the insulating film 16 formed on the top portions where no photoresist is formed.

### Bonding Step (Step S4)

Subsequently, as shown in FIG. 1D, the connection surfaces of the microbumps 14 (that is, the top portion of the first microbump 14 on the substrate 10 and the top portion of the second microbump 14 on the semiconductor chip 12) are bonded together. In the present step, the insulating film 16 remains on an exposed surface where an underfill material is to be filled, that is, the insulating film 16 remains on the surface of the substrate 10 facing the semiconductor chip 12 other than bonding surfaces (that is, the connection surfaces of the microbumps 14) of the substrate 10 and the semiconductor chip 12, and on the surface of the semiconductor chip 12 facing the substrate 10 other than the bonding surfaces of the substrate 10 and the semiconductor chip 12.

### Underfill Film Forming Step (Step S5)

Subsequently, as shown in FIG. 1E, an underfill film 18 is formed by filling the underfill material between the substrate 10 and the semiconductor chip 12 in a state where the substrate 10 and the semiconductor chip 12 are bonded together by the microbumps 14 and the insulating film 16 remains on the exposed surface where the underfill material is to be filled. As the underfill material, for example, a resin may be used. As the resin, for example, a substance such as an epoxy resin may be used.

In a manner described above, the surfaces of the substrate 10 and the semiconductor chip 12 and surfaces of the microbumps 14 between the substrate 10 and the semiconductor chip 12 after bonded together by the microbumps 14 are covered with the insulating film 16, and the underfill film 18 is filled into a surface of the insulating film 16. Thereby, the semiconductor device 101 is formed.

For example, when the substrate 10 and the semiconductor chip 12 are bonded together by the microbumps 14 and the underfill material is filled between the substrate 10 and the semiconductor chip 12, a void due to a poor filling may occur. It is considered that such a void occurs due to the fact that a plurality of components (structures) are provided on the surface of the substrate 10, the surface of the semiconductor chip 12 and the surfaces of the microbumps 14, that is, the exposed surface where an underfill material is to be filled. When attempting to fill the underfill material, the plurality of components (structures) may serve as an obstacle. Thereby, it may be difficult to uniformly fill the underfill material. As a result, differences in a wettability of the underfill material may occur. Such a phenomenon may become remarkable when a pitch between the substrate 10 and the semiconductor chip 12 where the underfill material is to be filled is miniaturized. According to the technique of the present disclosure, before filling the underfill material, the insulating film 16 is formed on the surfaces on which the underfill material is to be filled (that is, the exposed surfaces of the substrate 10, the semiconductor chip 12 and the microbumps 14). Thereby, since at least the surfaces on which the underfill material is to be filled are covered with the insulating film 16, it is possible to uniformly supply the underfill material. Therefore, it is possible to prevent the differences in the wettability between the surfaces of the substrate 10, the semiconductor chip 12 and the microbumps 14, and it is also possible to suppress an occurrence of the void when filling the underfill material. As a result, it is possible to suppress an increase in an electrical resistance of the semiconductor device 101 by increasing characteristics such as a strength and a heat dissipation property, and it is also possible to improve characteristics of the semiconductor device 101 such as a durability and electrical characteristics.

### (2) Configuration of Substrate Processing Apparatus

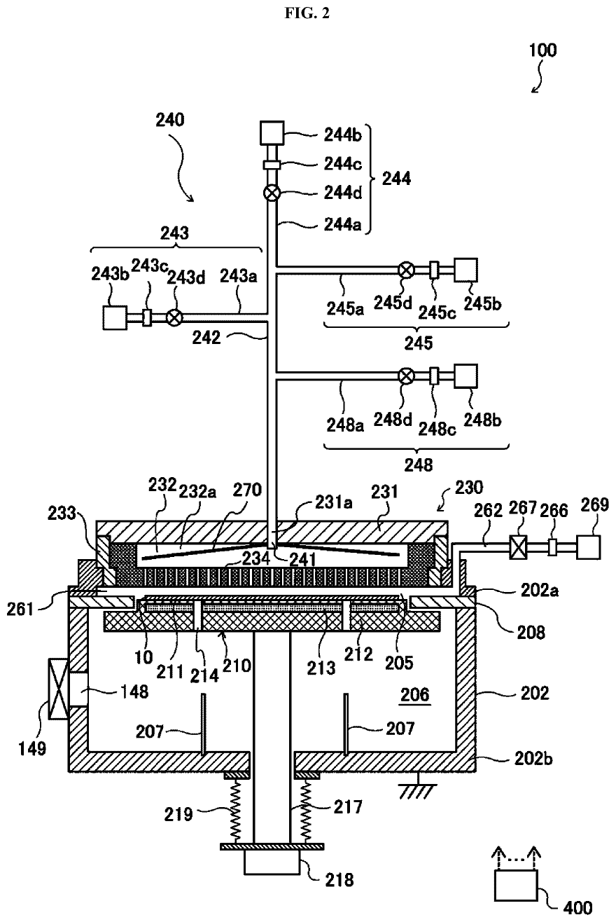

FIG. 2 is a diagram schematically illustrating an exemplary configuration of the substrate processing apparatus 100 used in the insulating film forming step S2 mentioned above. In addition, the substrate processing apparatus 100 is configured to be capable of processing the substrate 10 and the semiconductor chip 12 separately (respectively) or simultaneously when forming the insulating film 16 on the surfaces of the substrate 10 and the semiconductor chip 12 mentioned above. In the following description, an example in which the substrate 10 is processed will be described.

The substrate processing apparatus 100 includes a vessel 202. A process space 205 in which the substrate 10 is processed and a transfer space 206 through which the substrate 10 is transferred into or out of the process space 205 are provided in the vessel 202. The vessel 202 is constituted by an upper vessel 202a and a lower vessel 202b. A partition plate 208 is provided between the upper vessel 202a and the lower vessel 202b.

A substrate loading/unloading port 148 is provided adjacent to a gate valve 149 at a side surface of the lower vessel 202b. The substrate 10 is moved (transferred) between the transfer space 206 and a transfer chamber (not shown) through the substrate loading/unloading port 148. A plurality of lift pins 207 are provided at a bottom (lower portion) of the lower vessel 202b. In addition, the lower vessel 202b is electrically grounded.

A substrate support 210 configured to support the substrate 10 is provided in the process space 205. The substrate support 210 mainly includes: a substrate mounting table 212 provided with a substrate placing surface 211 on a surface thereof, where the substrate 10 is placed on the substrate placing surface 211; and a heater 213 serving as a heating structure provided in the substrate mounting table 212. A plurality of through-holes 214 through which the lift pins 207 penetrate are provided at positions of the substrate mounting table 212 corresponding to the lift pins 207.

The substrate mounting table 212 is supported by a shaft 217. The shaft 217 penetrates the bottom of the vessel 202, and is connected to an elevator (which is an elevating structure) 218 at an outside of the vessel 202.

The substrate mounting table 212 is configured such that the substrate 10 placed on the substrate placing surface 211 can be elevated or lowered by operating the elevator 218 to elevate or lower the shaft 217 and the substrate mounting table 212. In addition, a bellows 219 covers a periphery of a lower end of the shaft 217 to maintain the process space 205 airtight.

When the substrate 10 is transferred, the substrate mounting table 212 is lowered until the substrate placing surface 211 faces the substrate loading/unloading port 148, that is, until a transfer position of the substrate 10 is reached. When the substrate 10 is processed, the substrate mounting table 212 is elevated until the substrate 10 reaches a processing position in the process space 205 as shown in FIG. 2.

A shower head 230 serving as a gas dispersion structure is provided in an upper portion (upstream side) of the process space 205. A lid 231 of the shower head 230 is provided with a through-hole 231a. The through-hole 231a is configured to communicate with a common gas supply pipe 242 described later. A buffer chamber 232a provided with a buffer space 232 therein is provided in the shower head 230. A gas is supplied to the process space 205 through the buffer space 232.

A gas guide 270 such as a gas guide plate is provided in the buffer space 232. For example, the gas guide 270 is of a conic shape around a gas introduction port 241, and a diameter of the gas guide 270 increases along a radial direction of the substrate 10. The gas guide 270 is configured such that a lower end of an edge of the gas guide 270 is located outside an edge (end) of the substrate 10. The gas guide 270 is configured to efficiently guide the gas supplied thereto in a direction of a dispersion plate 234 described later.

The upper vessel 202a is provided with a flange (not shown). A support block 233 is placed on and fixed to the flange. The support block 233 includes a flange 233a. The dispersion plate 234 provided with a plurality of gas supply holes is placed on and fixed to the support block 233. Further, the lid 231 is fixed to an upper surface of the support block 233.

Subsequently, a gas supplier (which is a gas supply structure or a gas supply system) 240 will be described. A first gas supply pipe 243a, a second gas supply pipe 244a, a third gas supply pipe 245a and a fourth gas supply pipe 248a are connected to the common gas supply pipe 242.

A first gas supply source 243b, a mass flow controller (MFC) 243c serving as a flow rate controller (flow rate control structure) and a valve 243d serving as an opening/closing valve are sequentially provided at the first gas supply pipe 243a in this order from an upstream side toward a downstream side of the first gas supply pipe 243a in a gas flow direction.

The first gas supply source 243b is a source of a source gas. The source gas serves as one of process gases.

For example, a first gas supplier (which is a first gas supply structure or a first gas supply system) 243 is constituted mainly by the first gas supply pipe 243a, the MFC 243c and the valve 243d. The first gas supplier 243 may also be referred to as a “source gas supplier” which is a source gas supply structure or a source gas supply system) or as a “silicon-containing gas supplier” which is a silicon-containing gas supply structure or a silicon-containing gas supply system). The first gas supplier 243 may further include the first gas supply source 243b.

A second gas supply source 244b, a mass flow controller (MFC) 244c and a valve 244d are sequentially provided at the second gas supply pipe 244a in this order from an upstream side toward a downstream side of the second gas supply pipe 244a in the gas flow direction.

The second gas supply source 244b is a source of a reactive gas reactable with the source gas. The reactive gas serves as one of the process gases.

A second gas supplier (which is a second gas supply structure or a second gas supply system) 244 is constituted mainly by the second gas supply pipe 244a, the MFC 244c and the valve 244d. The second gas supplier 244 may also be referred to as a “reactive gas supplier” (which is a reactive gas supply structure or a reactive gas supply system), as an “oxidizing gas supplier” (which is an oxidizing gas supply structure or an oxidizing gas supply system), or as an “oxygen-containing gas supplier” (which is an oxygen-containing gas supply structure or an oxygen-containing gas supply system). In addition, the second gas supplier 244 may further include the second gas supply source 244b.

A third gas supply source 245b, a mass flow controller (MFC) 245c and a valve 245d are sequentially provided at the third gas supply pipe 245a in this order from an upstream side toward a downstream side of the third gas supply pipe 245a in the gas flow direction.

The third gas supply source 245b is a source of a reducing gas. The reducing gas serves as one of the process gases. Hereinafter, each of the process gases may also be referred to as a “process gas”.

A third gas supplier (which is a third gas supply structure or a third gas supply system) 245 is constituted mainly by the third gas supply pipe 245a, the MFC 245c and the valve 245d. The third gas supplier 245 may also be referred to as a “reducing gas supplier” (which is a reducing gas supply structure or a reducing gas supply system). The third gas supplier 245 may further include the third gas supply source 245b.

A fourth gas supply source 248b, a mass flow controller (MFC) 248c and a valve 248d are sequentially provided at the fourth gas supply pipe 248a in this order from an upstream side toward a downstream side of the fourth gas supply pipe 248a in the gas flow direction.

The fourth gas supply source 248b is a source of an inert gas.

A fourth gas supplier (which is a fourth gas supply structure or a fourth gas supply system) 248 is constituted mainly by the fourth gas supply pipe 248a, the MFC 248c and the valve 248d. The fourth gas supplier 248 may also be referred to as an “inert gas supplier” (which is an inert gas supply structure or an inert gas supply system). The fourth gas supplier 248 may further include the fourth gas supply source 248b.

The inert gas supplied from the fourth gas supply source 248b serves as a purge gas for purging the gas remaining in the vessel 202 or the shower head 230 in a substrate processing described later.

In the present embodiment, one of the first gas supplier 243, the second gas supplier 244, the third gas supplier 245 and the fourth gas supplier 248 (or a combination thereof) may also be referred to as the “gas supplier”.

An exhaust pipe 262 communicates with the process space 205 via an exhaust buffer structure 261. The exhaust buffer structure 261 is of a circumferential shape so as to surround an outer periphery of the substrate 10. According to the present embodiment, the exhaust buffer structure 261 is provided between the partition plate 208 and the upper vessel 202a.

The exhaust pipe 262 is connected to the upper vessel 202a on an upper portion of the exhaust buffer structure 261 such that the exhaust pipe 262 communicates with the process space 205 via the exhaust buffer structure 261. An APC (Automatic Pressure Controller) 266 is provided at the exhaust pipe 262. The APC 266 serves as a pressure controller capable of controlling a pressure (inner pressure) of the process space 205 to a predetermined pressure. The APC 266 includes a valve structure (not shown) whose opening degree can be adjusted. The APC 266 is configured to adjust a conductance of the exhaust pipe 262 in accordance with an instruction from a controller 400 described later.

A valve 267 is provided at the exhaust pipe 262 on an upstream side of the APC 266. In addition, a vacuum pump 269 is provided at a downstream side of the exhaust pipe 262. The vacuum pump 269 is configured to exhaust an atmosphere (inner atmosphere) of the process space 205 via the exhaust pipe 262. The exhaust pipe 262, the valve 267 and the APC 266 may be collectively referred to as an “exhauster” which is an exhaust structure or an exhaust system. The exhauster may further include the vacuum pump 269.

### Control Configuration (Controller)

Subsequently, the controller 400 serving as a control structure (control apparatus) configured to control operations of components constituting the substrate processing apparatus 100 will be described.

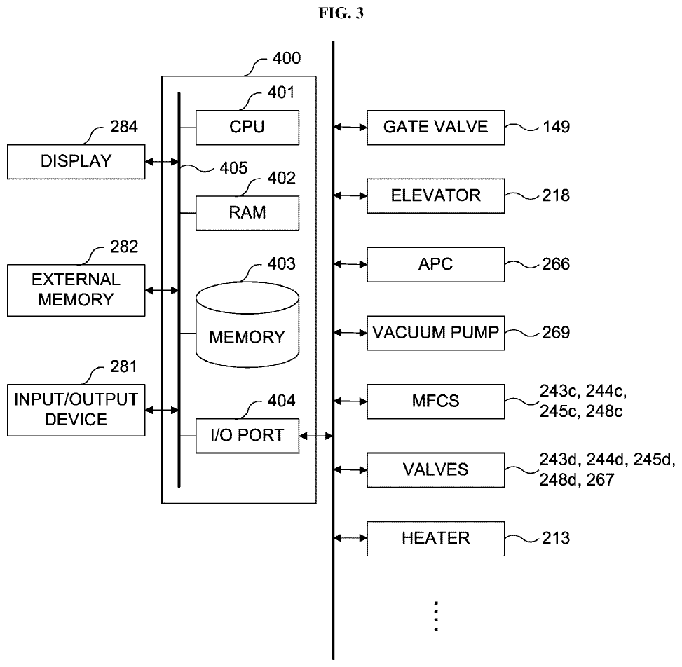

FIG. 3 is a diagram schematically illustrating a configuration of the controller 400. The controller 400 may be embodied by a computer including a CPU (Central Processing Unit) 401, a RAM (Random Access Memory) 402, a memory 403 serving as a storage and an I/O port (input/output port) 404. The RAM 402, the memory 403 and the I/O port 404 may exchange data with the CPU 401 via an internal bus 405.

The controller 400 is configured such that an input/output device 281 constituted by a component such as a keyboard and an external memory 282 are capable of being connected thereto.

A display (which is a display apparatus) 284 is configured to display data detected by each monitor (which is a monitoring apparatus). For example, in the present embodiment, the display 284 is described as a separate component from the input/output device 281. However, the present embodiment is not limited thereto. For example, when the input/output device 281 also functions as a display screen such as a touch panel, the input/output device 281 and the display 284 may be configured as a single component.

The memory 403 may be embodied by a component such as a flash memory and a HDD (Hard Disk Drive). For example, a process recipe (also referred to as a “recipe program”) in which information such as procedures and the conditions of the substrate processing described later is stored, a control program for controlling operations of the substrate processing apparatus 100 to perform the process recipe, or a table may be readably stored in the memory 403. The process recipe (recipe program) is obtained by combining steps (procedures) of the substrate processing described later such that the controller 400 can execute the steps to acquire a predetermined result, and functions as a program. Hereinafter, the process recipe (recipe program) and the control program may be collectively or individually referred to simply as a “program”. Thus, in the present specification, the term “program” may refer to the process recipe alone, may refer to the control program alone, or may refer to both of the process recipe and the control program. In addition, the RAM 402 serves as a memory area in which the program or data read by the CPU 401 is temporarily stored.

The I/O port 404 is electrically connected to the components of the substrate processing apparatus 100 mentioned above such as the gate valve 149, the elevator 218, the APC 266, the vacuum pump 269, the MFC 243c, 244c, 245c and 248c, the valves 243d, 244d, 245d, 248d and 267 and the heater 213.

The CPU 401 is configured to read and execute the control program from the memory 403 and read the process recipe (recipe program) in accordance with an instruction such as an operation command inputted from the input/output device 281. The CPU 401 is configured to control various operations in accordance with the recipe program such as an opening and closing operation of the gate valve 149, an elevating and lowering operation of the elevator 218, an opening and closing operation of the APC 266, an on/off control operation of the vacuum pump 269, flow rate adjusting operations of the MFCs 243c, 244c, 245c and 248c, opening and closing operations of the valves 243d, 244d, 245d, 248d and 267, and a temperature control operation of the heater 213.

For example, the controller 400 according to the present embodiment may be embodied by preparing the external memory 282 (for example, a magnetic disk such as a hard disk, an optical disk such as a DVD, a magneto-optical disk such as an MO and a semiconductor memory such as a USB memory) storing the program mentioned above and installing the program onto the computer using the external memory 282. Further, a configuration capable of providing the program to the computer is not limited to the external memory 282. For example, the program may be directly provided to the computer by a communication interface such as the Internet and a dedicated line instead of the external memory 282. The memory 403 and the external memory 282 may be embodied by a non-transitory computer-readable recording medium. Hereinafter, the memory 403 and the external memory 282 may be collectively or individually referred to as a “recording medium”. Thus, in the present specification, the term “recording medium” may refer to the memory 403 alone, may refer to the external memory 282 alone, or may refer to both of the memory 403 and the external memory 282.

### (4) Substrate Processing

Hereinafter, as a part of the manufacturing process of the semiconductor device, the insulating film forming step S2 of forming the insulating film 16 mentioned above using the substrate processing apparatus 100 will be described. In the following description, the operations of the components constituting the substrate processing apparatus 100 are controlled by the controller 400. In addition, a process of forming the insulating film 16 on the surface of the substrate 10 is similar to a process of forming the insulating film 16 on the surface of the semiconductor chip 12. Thus, in the following description, the term “substrate 10” may be replaced with the term “semiconductor chip 12” when describing the process of forming the insulating film 16 on the surface of the semiconductor chip 12. Hereinafter, the insulating film forming step S2 will be described by way of an example in which the insulating film 16 is formed on the surface of the substrate 10.

For example, in the present specification, the term “substrate” may refer to “a substrate itself”, or may refer to “a substrate and a stacked structure (aggregated structure) of a predetermined layer (or layers) or a film (or films) formed on a surface of the substrate”. That is, the term “substrate” may collectively refer to “a substrate and layers or films formed on a surface of the substrate”. Further, in the present specification, the term “a surface of a substrate” may refer to “a surface (exposed surface) of a substrate itself”, or may refer to “a surface of a predetermined layer or a film formed on a substrate, i.e. a top surface (uppermost surface) of the substrate as a stacked structure”.

Thus, in the present specification, the term “supplying a predetermined gas to a substrate” may refer to “directly supplying a predetermined gas to a surface (exposed surface) of a substrate itself”, or may refer to “supplying a predetermined gas to a layer or a film formed on a substrate”, that is, “supplying a predetermined gas to a top surface (uppermost surface) of a substrate as a stacked structure”. In addition, in the present specification, the term “forming a predetermined layer (or film) on a substrate” may refer to “forming a predetermined layer (or film) directly on a surface (exposed surface) of a substrate itself” or may refer to “forming a predetermined layer (or film) on a layer (or film) formed on a substrate, i.e. a top surface (uppermost surface) of the substrate as a stacked structure”.

In the present specification, the term “wafer” and the term “substrate” may be used as substantially the same meaning. In such a case, the term “substrate” in the above description may be replaced with the term “wafer”.

### Substrate Loading and Placing Step

The substrate mounting table 212 is lowered to the transfer position of the substrate 10 such that the lift pins 207 penetrate through the through-holes 214 of the substrate mounting table 212. As a result, the lift pins 207 protrude from the surface of the substrate mounting table 212 by a predetermined height. Subsequently, the gate valve 149 is opened, and the substrate 10 is loaded (transferred) into the process space 205 by using a substrate transfer structure (not shown). Then, the substrate 10 is transferred onto the lift pins 207. Thereby, the substrate 10 is placed on and supported by the lift pins 207 (which protrude from the surface of the substrate mounting table 212) in a horizontal orientation.

After the substrate 10 is loaded into the vessel 202, the substrate transfer structure is retracted to a position outside the vessel 202, and the gate valve 149 is closed to hermetically seal (or close) an inside (inner portion) of the vessel 202. Thereafter, by elevating the substrate mounting table 212, the substrate 10 is placed on and supported by the substrate placing surface 211 of the substrate mounting table 212.

In addition, when the substrate 10 is loaded into the vessel 202, it is preferable to supply the inert gas via the fourth gas supplier 248 into the vessel 202 while exhausting an atmosphere (inner atmosphere) of the vessel 202 with the exhauster. That is, it is preferable to supply the inert gas into the vessel 202 by opening at least the valve 248d of the fourth gas supplier 248 in a state where the inner atmosphere of the vessel 202 is exhausted by operating the vacuum pump 269 and opening the APC 266. In addition, the vacuum pump 269 continuously exhausts the inner atmosphere of the vessel 202 until at least the steps from the substrate loading and placing step to a substrate unloading step described later are completed.

### Film Forming Step, S10

Then, a film forming step S10 is performed by performing a source gas supply step S101 and a reactive gas supply step S102 a predetermined number of times (n times, where n is an integer of 1 or more).

### Source Gas Supply Step, S101

After the substrate mounting table 212 is moved to the processing position of the substrate 10, the inner atmosphere of the process space 205 is exhausted through the exhaust pipe 262 to adjust the inner pressure of the process space 205.

When the temperature of the substrate 10 reach a predetermined temperature (for example 200° C. or less) while adjusting the inner pressure of the process space 205 to a predetermined pressure, the valve 243d is opened to start a supply of the source gas into the process space 205 through the common gas supply pipe 242 and the shower head 230. In the present step, the MFC 243c is adjusted such that a flow rate of the source gas is adjusted to a predetermined flow rate. In the present step, the inner atmosphere of the process space 205 is exhausted through the exhaust pipe 262. By supplying the source gas, a first layer is formed on the substrate 10. After a predetermined time has elapsed from the supply of the source gas, the valve 243d is closed to stop the supply of the source gas.

Subsequently, the valve 248d is opened to supply the inert gas into the process space 205 through the common gas supply pipe 242 and the shower head 230. Thereby, the process space 205 is purged.

In the present embodiment, as the source gas, for example, a silicon-containing gas, that is, a gas containing silicon (Si) may be used. Specifically, as the silicon-containing gas, for example, a gas such as tetraethoxysilane (Si(OC₂H₅)₄, abbreviated as TEOS) gas, monosilane (SiH₄) gas, dichlorosilane (SiH₂Cl₂, abbreviated as DCS) gas and hexachlorodisilane (Si₂Cl₆, abbreviated as HCDS) gas may be used. As the silicon-containing gas, for example, one or more of the gases exemplified above may be used.

For example, by supplying the silicon-containing gas to the substrate 10, a silicon-containing layer serving as the first layer is formed on the surface of the substrate 10.

As the inert gas, for example, nitrogen (N₂) gas or a rare gas such as argon (Ar) gas, helium (He) gas, neon (Ne) gas and xenon (Xe) gas may be used. One or more of the gases exemplified above may be used as the inert gas. The same also applies to each step described below.

### Reactive Gas Supply Step, S102

Subsequently, the valve 244d is opened to start a supply of the reactive gas into the process space 205 through the common gas supply pipe 242 and the shower head 230. In the present step, the MFC 244c is adjusted such that a flow rate of the reactive gas is adjusted to a predetermined flow rate. When the reactive gas is supplied, the reactive gas reacts with the first layer on the substrate 10. Thereby, a second layer is formed on the substrate 10.

After the second layer is formed on the substrate 10, the valve 244d is closed to stop the supply of the reactive gas into the process space 205.

Subsequently, the valve 248d is opened to supply the inert gas into the process space 205 through the common gas supply pipe 242 and the shower head 230. Thereby, the process space 205 is purged.

In the present embodiment, as the reactive gas, for example, an oxygen-containing gas, that is, a gas containing oxygen (O) may be used. The oxygen-containing gas may also be referred to as an “oxidizing gas”. As the oxygen-containing gas, for example, a gas such as oxygen (O₂) gas, ozone (O₃) gas, a gaseous mixture of the O₂ gas and hydrogen (H₂) gas, water vapor (H₂O gas), hydrogen peroxide (H₂O₂) gas, nitrous oxide (N₂O) gas, nitric oxide (NO) gas, nitrogen dioxide (NO₂) gas, carbon monoxide (CO) gas and carbon dioxide (CO₂) gas may be used. One or more of the gases exemplified above may be used as the oxygen-containing gas.

For example, by supplying the oxygen-containing gas to the substrate 10, the silicon-containing layer on the substrate 10 is oxidized to form a silicon oxide layer (SiO layer) on the substrate 10.

### Performing Predetermined Number of Times

By performing a cycle wherein the steps S101 and S102 are performed a predetermined number of times (n times, wherein n is an integer of 1 or more), it is possible to form the insulating film 16 of a desired thickness on the substrate 10. For example, as the insulating film 16, a silicon oxide film (SiO film) is formed. For example, the thickness of the insulating film 16 formed in the present step is set to be 50 nm or less.

For example, the present embodiment is described by way of an example in which the silicon oxide film is formed as the insulating film 16 in the film forming step S10 mentioned above. However, the technique of the present disclosure is not limited thereto. For example, by providing a nitrogen-containing gas supplier (which is a nitrogen-containing gas supply structure or a nitrogen-containing gas supply system), a film such as a silicon oxynitride film (SiON film) may be formed as the insulating film 16 in the film forming step S10 mentioned above. The nitrogen-containing gas is a gas containing nitrogen (N), and may also be referred to as a “nitriding gas”.

For example, the present embodiment is described by way of an example in which the source gas and the reactive gas are cyclically supplied in the film forming step S10 mentioned above. However, the technique of the present disclosure is not limited thereto. For example, the source gas and the reactive gas may be supplied simultaneously, or the insulating film 16 may be formed by supplying the source gas alone without using the reactive gas.

### Reducing Step, S11

Subsequently, the valve 245d is opened to start a supply of the reducing gas into the process space 205 through the common gas supply pipe 242 and the shower head 230. In the present step, the MFC 245c is adjusted such that a flow rate of the reducing gas is adjusted to a predetermined flow rate. In the present step, the inner atmosphere of the process space 205 is exhausted through the exhaust pipe 262. By supplying the reducing gas, the substrate 10 with the insulating film 16 formed thereon is exposed to a reducing atmosphere. After a predetermined time has elapsed from the supply of the reducing gas, the valve 245d is closed to stop the supply of the reducing gas. In the present step, a base metal film (underlying metal film) oxidized by performing the film forming step S10 is reduced.

Subsequently, the valve 248d is opened to supply the inert gas into the process space 205 through the common gas supply pipe 242 and the shower head 230. Thereby, the process space 205 is purged.

In the present embodiment, as the reducing gas, for example, a hydrogen-containing gas, that is, a gas containing hydrogen (H) may be used. As the hydrogen-containing gas, for example, a gas such as hydrogen (H₂) gas may be used.

### Performing Predetermined Number of Times, S12

A cycle wherein the step S10 and the step S11 are performed is performed a predetermined number of times (m times, wherein m is an integer of 1 or more), that is, at least once.

In a manner mentioned above, by the ALD method or the CVD method, the insulating film 16 is formed on the first surface of the substrate 10 (which is the front surface of the substrate 10 facing the semiconductor chip 12 when the substrate 10 and the semiconductor chip 12 are bonded together) where the first microbumps 14 are provided and the second surface of the semiconductor chip 12 (which is the front surface of the semiconductor chip 12 facing the substrate 10 when the substrate 10 and the semiconductor chip 12 are bonded together) where the second microbumps 14 are provided. In the insulating film forming step S2, by performing the film forming step S10 and the reducing step S11 the predetermined number of times (m times), it is possible to form the insulating film 16 on the first surface of the substrate 10, the surface of the first microbumps 14, the second surface of the semiconductor chip 12 and the surface of the second microbumps 14 while suppressing an oxidation of the microbumps 14.

### Substrate Unloading Step

Subsequently, the substrate mounting table 212 is lowered until the substrate 10 is placed on the lift pins 207 protruding from the surface of the substrate mounting table 212. Then, the gate valve 149 is opened, and the substrate 10 is transferred (unloaded) out of the vessel 202 by using the substrate transfer structure (not shown).

### (5) Other Embodiments

Subsequently, other embodiments of the manufacturing process of the semiconductor device 101 mentioned above will be described in detail. In the following description, portions (features) different from those of the first embodiment will be described in detail below, and the description of portions the same as the first embodiment will be omitted.

### Second Embodiment

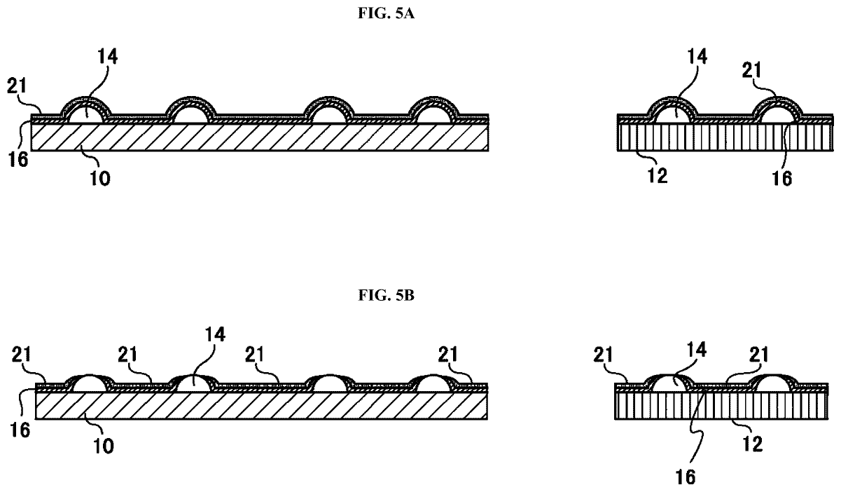

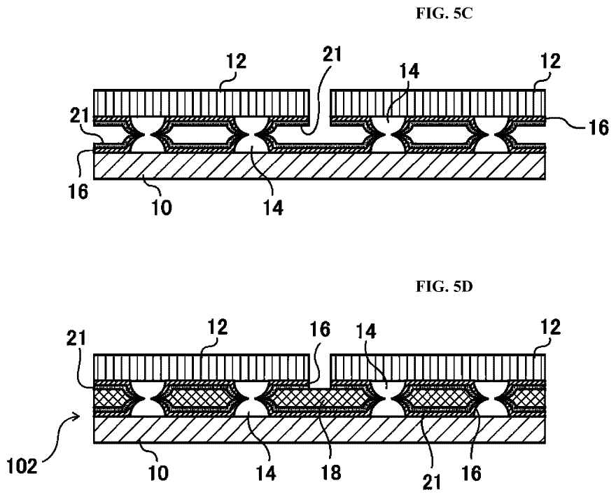

FIGS. 5A to 5D are diagrams schematically illustrating steps in a manufacturing process of a semiconductor device 102 according to a second embodiment of the present disclosure. According to the second embodiment, the following steps are performed after the microbump forming step S1 and the insulating film forming step S2 mentioned above. In the following description, portions (features) of the second embodiment different from those of the first embodiment will be described in detail below, and the description of portions of the second embodiment the same as the first embodiment will be omitted.

### Conductive Film Forming Step, S21

As shown in FIG. 5A, a conductive film 21 is formed on the surface of the substrate 10 and the surface of the semiconductor chip 12. On the surface of the substrate 10 and the surface of the semiconductor chip 12, the microbumps 14 are provided and the insulating film 16 is formed. That is, the conductive film 21 is formed on the insulating film 16 formed on each of the substrate 10, the semiconductor chip 12 and the microbumps 14. For example, by providing a metal-containing gas supplier (which is a metal-containing gas supply structure or a metal-containing gas supply system) configured to supply a metal-containing gas in the substrate processing apparatus 100 mentioned above and by supplying the metal-containing gas, it is possible to form the conductive film 21. The metal-containing gas is a gas containing a metal element.

### Conductive Film and Insulating Film Removing Step, S22

Subsequently, as shown in FIG. 5B, the conductive film 21 and the insulating film 16 formed on the top portion of the first microbump 14 on the surface of the substrate 10 and the conductive film 21 and the insulating film 16 formed on the top portion of the second microbump 14 on the surface of the semiconductor chip 12 are removed to expose the top portions of the microbumps 14 on the surface of the substrate 10 and the surface of the semiconductor chip 12. The top portions of the microbumps 14 on the surface of the substrate 10 and the surface of the semiconductor chip 12 serve as the connection surfaces of the microbumps 14 on the surface of the substrate 10 and the surface of the semiconductor chip 12. For example, the conductive film 21 and the insulating film 16 formed on the top portions of the microbumps 14 are removed by the CMP process. However, the present step is not limited to the CMP process. For example, the conductive film 21 and the insulating film 16 formed on the top portions of the microbumps 14 may be removed by the dry etching process. In other words, according to the present embodiment, instead of the step S22, the conductive film forming step S21 mentioned above may be performed between the insulating film forming step S2 and the insulating film removing step S3 mentioned above, and in the insulating film removing step S3 mentioned above, the conductive film 21 and the insulating film 16 formed on the connection surfaces of the microbumps 14 may be removed.

### Bonding Step, S23

Subsequently, as shown in FIG. 5C, the connection surfaces of the microbumps 14 (that is, the top portion of the first microbump 14 on the substrate 10 and the top portion of the second microbump 14 on the semiconductor chip 12) are bonded together. In the present step, the conductive film 21 remains on an exposed surface where the underfill material is to be filled, that is, the conductive film 21 remains on the surface of the substrate 10 facing the semiconductor chip 12 other than the bonding surfaces (that is, the connection surfaces of the microbumps 14) of the substrate 10 and the semiconductor chip 12, and on the surface of the semiconductor chip 12 facing the substrate 10 other than the bonding surfaces of the substrate 10 and the semiconductor chip 12.

Subsequently, as shown in FIG. 5D, the underfill film 18 is formed by filling the underfill material between the substrate 10 and the semiconductor chip 12 in a state where the substrate 10 and the semiconductor chip 12 are bonded together by the microbumps 14 and the conductive film 21 remains on the exposed surface where the underfill material is to be filled.

In a manner described above, the surfaces of the substrate 10 and the semiconductor chip 12 and the surfaces of the microbumps 14 between the substrate 10 and the semiconductor chip 12 after bonded together by the microbumps 14 are covered with the insulating film 16, the conductive film 21 is formed on the insulating film 16, and the underfill film 18 is filled into a surface of the conductive film 21. Thereby, the semiconductor device 102 is formed.

According to the present embodiment, it is possible to obtain substantially the same effects as in the embodiments mentioned above. That is, since the exposed surface into which the underfill material is to be filled is a type of the conductive film 21, it is possible to prevent the differences in the wettability between the surfaces of the substrate 10, the semiconductor chip 12 and the microbumps 14, and it is also possible to suppress the occurrence of the void, when filling the underfill material. In addition, according to the present embodiment, it is possible to form the conductive film 21 whose thermal emissivity is high on the insulating film 16 on the surfaces of the substrate 10 and the semiconductor chip 12, in particular, between the insulating film 16 and the underfill film 18. Therefore, since a heat accumulation during an operation of the semiconductor device 102 can be suppressed, it is possible to perform a high voltage operation of the semiconductor device 102 and it is also possible to improve an operating speed of the semiconductor device 102.

### Third Embodiment

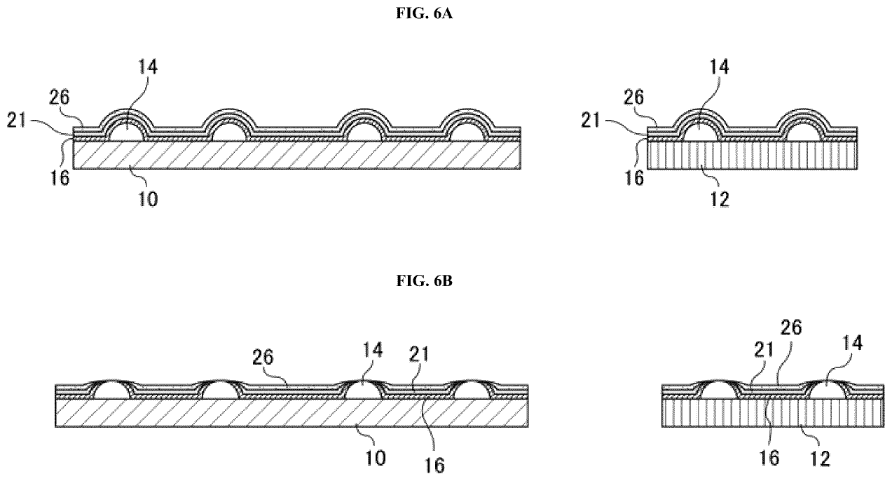

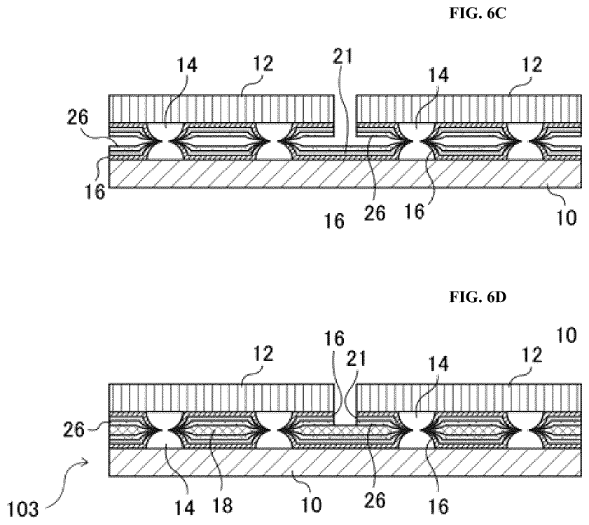

FIGS. 6A to 6D are diagrams schematically illustrating steps in a manufacturing process of a semiconductor device 103 according to a third embodiment of the present disclosure. According to the third embodiment, the following steps are performed after the microbump forming step S1, the insulating film forming step S2 and the conductive film forming step S21 mentioned above.

### Organic Group-Containing Insulating Film Forming Step, S211

As shown in FIG. 6A, an organic group-containing insulating film (also referred to as an “organic insulating film”) 26 is formed on the surface of the substrate 10 and the surface of the semiconductor chip 12. On the surface of the substrate 10 and the surface of the semiconductor chip 12, the microbumps 14 are provided and the conductive film 21 is formed. That is, the organic group-containing insulating film 26 is formed on the conductive film 21 formed on each of the substrate 10, the semiconductor chip 12 and the microbumps 14. For example, by providing an organic group-containing source gas supplier (which is an organic group-containing source gas supply structure or an organic group-containing source gas supply system) configured to supply an organic group-containing source gas in the substrate processing apparatus 100 mentioned above and by supplying the organic group-containing source gas, it is possible to form the organic group-containing insulating film 26. The organic group-containing source gas is a gas containing an organic group-containing source material. In addition, for example, the insulating film 16 is an inorganic insulating film.

### Organic Group-Containing Insulating Film, Conductive Film and Insulating Film Removing Step, S212

Subsequently, as shown in FIG. 6B, the organic group-containing insulating film 26, the conductive film 21 and the insulating film 16 formed on the top portion of the first microbump 14 on the surface of the substrate 10 and the organic group-containing insulating film 26, the conductive film 21 and the insulating film 16 formed on the top portion of the second microbump 14 on the surface of the semiconductor chip 12 are removed to expose the top portions of the microbumps 14 on the surface of the substrate 10 and the surface of the semiconductor chip 12. The top portions of the microbumps 14 on the surface of the substrate 10 and the surface of the semiconductor chip 12 serve as the connection surfaces of the microbumps 14 on the surface of the substrate 10 and the surface of the semiconductor chip 12. For example, the organic group-containing insulating film 26, the conductive film 21 and the insulating film 16 formed on the top portions of the microbumps 14 are removed by the CMP process. However, the present step is not limited to the CMP process. For example, the organic group-containing insulating film 26, the conductive film 21 and the insulating film 16 formed on the top portions of the microbumps 14 may be removed by the dry etching process. In other words, according to the present embodiment, instead of the step S212, the organic group-containing insulating film forming step S211 mentioned above may be performed between the conductive film forming step S21 and the conductive film and insulating film removing step S22 mentioned above, and in the conductive film and insulating film removing step S22 mentioned above, the organic group-containing insulating film 26, the conductive film 21 and the insulating film 16 formed on the connection surfaces of the microbumps 14 may be removed.

### Bonding Step, S213

Subsequently, as shown in FIG. 6C, the connection surfaces of the microbumps 14 (that is, the top portion of the first microbump 14 on the substrate 10 and the top portion of the second microbump 14 on the semiconductor chip 12) are bonded together. In the present step, the organic group-containing insulating film 26 remains on the exposed surface where the underfill material is to be filled, that is, the organic group-containing insulating film 26 remains on the surface of the substrate 10 facing the semiconductor chip 12 other than the bonding surfaces (that is, the connection surfaces of the microbumps 14) of the substrate 10 and the semiconductor chip 12, and on the surface of the semiconductor chip 12 facing the substrate 10 other than the bonding surfaces of the substrate 10 and the semiconductor chip 12.

### Underfill Film Forming Step, S214

Subsequently, as shown in FIG. 6D, the underfill film 18 is formed by filling the underfill material between the substrate 10 and the semiconductor chip 12 in a state where the substrate 10 and the semiconductor chip 12 are bonded together by the microbumps 14 and the organic group-containing insulating film 26 remains on the exposed surface where the underfill material is to be filled.

In a manner described above, the surfaces of the substrate 10 and the semiconductor chip 12 and the surfaces of the microbumps 14 between the substrate 10 and the semiconductor chip 12 after bonded together by the microbumps 14 are covered with the insulating film 16, the conductive film 21 and the organic group-containing insulating film 26 is formed on the insulating film 16, and the underfill film 18 is filled into a surface of the organic group-containing insulating film 26. Thereby, the semiconductor device 103 is formed.

According to the present embodiment, it is possible to obtain substantially the same effects as in the embodiments mentioned above. That is, since the exposed surface into which the underfill material is to be filled is a type of the organic group-containing insulating film 26 and the plurality of components (structures) mentioned above are not provided on the exposed surface, it is possible to prevent the differences in the wettability between the surfaces of the substrate 10, the semiconductor chip 12 and the microbumps 14, and it is also possible to suppress the occurrence of the void, when filling the underfill material. In addition, according to the present embodiment, it is possible to form the organic group-containing insulating film 26 whose water repellency is high and whose wettability is high on the exposed surface where the underfill material is to be filled. Therefore, it is possible to further suppress the occurrence of the void when filling the underfill material. In addition, according to the present embodiment, it is possible to form the conductive film 21 whose thermal emissivity is high between the organic group-containing insulating film 26 and the insulating film 16 formed on the surfaces of the substrate 10 and the semiconductor chip 12. Therefore, since a heat accumulation during an operation of the semiconductor device 103 can be suppressed, it is possible to perform a high voltage operation of the semiconductor device 103 and it is also possible to improve an operating speed of the semiconductor device 103.

### Fourth Embodiment

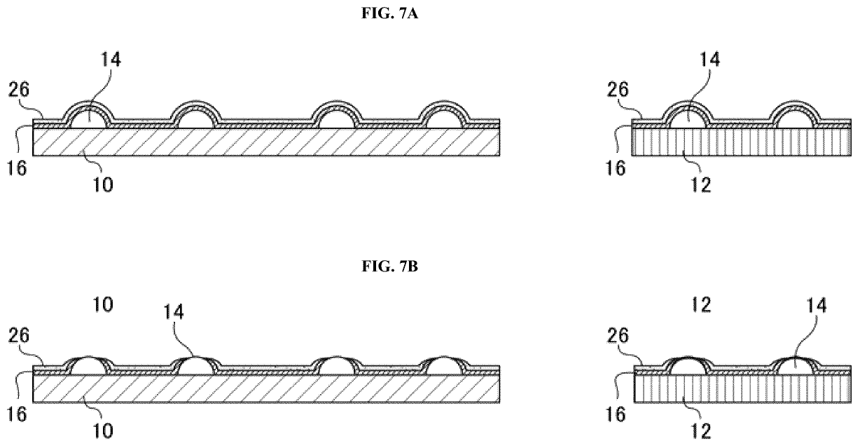

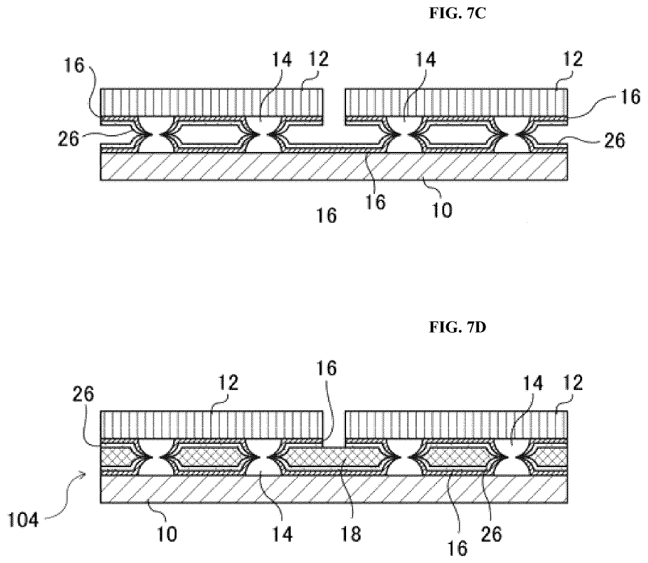

FIGS. 7A to 7D are diagrams schematically illustrating steps in a manufacturing process of a semiconductor device 104 according to a fourth embodiment of the present disclosure. According to the fourth embodiment, the following steps are performed after the microbump forming step S1 and the insulating film forming step S2 mentioned above.

### Organic Group-Containing Insulating Film Forming Step, S25

As shown in FIG. 7A, the organic group-containing insulating film 26 is formed on the surface of the substrate 10 and the surface of the semiconductor chip 12. On the surface of the substrate 10 and the surface of the semiconductor chip 12, the microbumps 14 are provided and the insulating film 16 is formed. That is, the organic group-containing insulating film 26 is formed on the insulating film 16 formed on each of the substrate 10, the semiconductor chip 12 and the microbumps 14. For example, by providing the organic group-containing source gas supplier configured to supply the organic group-containing source gas in the substrate processing apparatus 100 mentioned above and by supplying the organic group-containing source gas, it is possible to form the organic group-containing insulating film 26. As described above, the organic group-containing source gas is the gas containing the organic group-containing source material. For example, a total thickness of the organic group-containing insulating film 26 formed in the present step and the insulating film 16 formed in the present step is set to be 50 nm or less.

### Organic Group-Containing Insulating Film and Insulating Film Removing Step, S26

Subsequently, as shown in FIG. 7B, the organic group-containing insulating film 26 and the insulating film 16 formed on the top portion of the first microbump 14 on the surface of the substrate 10 and the organic group-containing insulating film 26 and the insulating film 16 formed on the top portion of the second microbump 14 on the surface of the semiconductor chip 12 are removed to expose the top portions of the microbumps 14 on the surface of the substrate 10 and the surface of the semiconductor chip 12. The top portions of the microbumps 14 on the surface of the substrate 10 and the surface of the semiconductor chip 12 serve as the connection surfaces of the microbumps 14 on the surface of the substrate 10 and the surface of the semiconductor chip 12. For example, the organic group-containing insulating film 26 and the insulating film 16 formed on the top portions of the microbumps 14 are removed by the CMP process. However, the present step is not limited to the CMP process. For example, the organic group-containing insulating film 26 and the insulating film 16 formed on the top portions of the microbumps 14 may be removed by the dry etching process. In other words, according to the present embodiment, instead of the step S26, the organic group-containing insulating film forming step S25 mentioned above may be performed between the insulating film forming step S2 and the insulating film removing step S3 mentioned above, and in the insulating film removing step S3 mentioned above, the organic group-containing insulating film 26 and the insulating film 16 formed on the connection surfaces of the microbumps 14 may be removed.

### Bonding Step, S27

Subsequently, as shown in FIG. 7C, the connection surfaces of the microbumps 14 (that is, the top portion of the first microbump 14 on the substrate 10 and the top portion of the second microbump 14 on the semiconductor chip 12) are bonded together. In the present step, the organic group-containing insulating film 26 remains on the exposed surface where the underfill material is to be filled, that is, the organic group-containing insulating film 26 remains on the surface of the substrate 10 facing the semiconductor chip 12 other than the bonding surfaces (that is, the connection surfaces of the microbumps 14) of the substrate 10 and the semiconductor chip 12, and on the surface of the semiconductor chip 12 facing the substrate 10 other than the bonding surfaces of the substrate 10 and the semiconductor chip 12.

### Underfill Film Forming Step, S28

Subsequently, as shown in FIG. 7D, the underfill film 18 is formed by filling the underfill material between the substrate 10 and the semiconductor chip 12 in a state where the substrate 10 and the semiconductor chip 12 are bonded together by the microbumps 14 and the organic group-containing insulating film 26 remains on the exposed surface where the underfill material is to be filled.

In a manner described above, the surfaces of the substrate 10 and the semiconductor chip 12 and the surfaces of the microbumps 14 between the substrate 10 and the semiconductor chip 12 after bonded together by the microbumps 14 are covered with the insulating film 16, the organic group-containing insulating film 26 is formed on the insulating film 16, and the underfill film 18 is filled into the surface of the organic group-containing insulating film 26. Thereby, the semiconductor device 104 is formed.

According to the present embodiment, it is possible to obtain substantially the same effects as in the embodiments mentioned above. That is, since the exposed surface into which the underfill material is to be filled is a type of the organic group-containing insulating film 26, it is possible to prevent the differences in the wettability between the surfaces of the substrate 10, the semiconductor chip 12 and the microbumps 14, and it is also possible to suppress the occurrence of the void, when filling the underfill material. In addition, according to the present embodiment, it is possible to further form the organic group-containing insulating film 26 whose water repellency is high and whose wettability is high on the exposed surface where the underfill material is to be filled. Therefore, it is possible to further suppress the occurrence of the void when filling the underfill material.

### Other Embodiments

While the technique of the present disclosure is described in detail by way of the embodiments mentioned above, the technique of the present disclosure is not limited thereto. For example, the technique of the present disclosure may be modified in various ways without departing from the scope thereof.

For example, the embodiments mentioned above are described by way of an example in which a single wafer type substrate processing apparatus capable of processing one or several substrates at once is used to process the film. However, the technique of the present disclosure is not limited thereto. For example, the technique of the present disclosure may be preferably applied when a batch type substrate processing apparatus capable of simultaneously processing a plurality of substrates is used to process the film. For example, the embodiments mentioned above are described by way of an example in which a substrate processing apparatus including a cold wall type process furnace is used to process the film. However, the technique of the present disclosure is not limited thereto. For example, the technique of the present disclosure may be preferably applied when a substrate processing apparatus including a hot wall type process furnace is used to process the film.

The process procedures and the process conditions of each process using the substrate processing apparatuses exemplified above may be substantially the same as those of the embodiments or modified examples mentioned above. Even in such a case, it is possible to obtain substantially the same effects as in the embodiments or the modified examples mentioned above.

For example, it is preferable that recipes (process recipes) used in processes are prepared individually in accordance with the contents of the processes and stored in the memory 403 in advance via an electric communication line or the external memory 282. When starting each process, it is preferable that the CPU 401 selects an appropriate recipe among the recipes stored in the memory 403 in accordance with the contents of each process. Thus, various films of different composition ratios, qualities and thicknesses can be formed in a reliably reproducible manner by using a single substrate processing apparatus (that is, the substrate processing apparatus 100 mentioned above). In addition, since a burden on an operating personnel can be reduced, various processes can be performed quickly while avoiding an error in operating the substrate processing apparatus 100.

The recipe mentioned above is not limited to creating a new recipe. For example, the recipe may be prepared by changing an existing recipe stored (or installed) in the substrate processing apparatus 100 in advance. When changing the existing recipe to a new recipe, the new recipe may be installed in the substrate processing apparatus 100 via the electric communication line or a recording medium in which the new recipe is stored. In addition, the existing recipe already stored in the substrate processing apparatus 100 may be directly changed to the new recipe by operating the input/output device 281 of the substrate processing apparatus 100.

Further, the embodiments mentioned above may be appropriately combined. The process procedures and the process conditions of each combination thereof may be substantially the same as those of the embodiments mentioned above.

As described above, according to some embodiments of the present disclosure, it is possible to suppress the occurrence of the void when the underfill material is filled between the substrate and the semiconductor chip.

What is claimed is:

1. A substrate processing method comprising:
(a) forming a first microbump on a first surface of a substrate, wherein the first surface faces a semiconductor chip when the substrate and the semiconductor chip are bonded together;
(b) forming a second microbump on a second surface of the semiconductor chip, wherein the second surface faces the substrate when the substrate and the semiconductor chip are bonded together;
(c) forming an insulating film on the first surface, the second surface, the first mircobump and the second microbump;
(d) removing the insulating film formed on a connection surface of the first mircobump and a connection surface of the second microbump; and
(e) bonding the connection surface of the first mircobump on the first surface and the connection surface of the second microbump on the second surface.

2. The substrate processing method of claim 1, wherein a thickness of the insulating film is set to be 50 nm or less.

3. The substrate processing method of claim 1, further comprising
(f) forming a conductive film on the insulating film between (c) and (d).

4. The substrate processing method of claim 3, wherein, in (d), the conductive film and the insulating film formed on the connection surface of the first mircobump and the connection surface of the second microbump are removed.

5. The substrate processing method of claim 1, wherein, in (d), the insulating film formed on the connection surface of the first mircobump and the connection surface of the second microbump is removed by a CMP (Chemical Mechanical Polishing) process or an etching process.

6. The substrate processing method of claim 1, further comprising
(g) forming an underfill film between the substrate and the semiconductor chip after (e).

7. The substrate processing method of claim 1, wherein the insulating film is capable of being formed on: another insulating film on the first surface or the second surface; a metal film on the first surface or the second surface; the first microbump: and the second microbump.

8. The substrate processing method of claim 1, wherein (c) comprises:
(c-1) forming a first insulating film on the first surface, the first microbump, the second surface and the second microbump; and
(c-2) forming a second insulating film on the first insulating film,
wherein the second insulating film comprises an organic group-containing insulating film.

9. The substrate processing method of claim 8, further comprising
(h) forming a conductive film between (c-1) and (c-2).

10. The substrate processing method of claim 9, wherein, in (d), the conductive film, the first insulating film and the second insulating film formed on the connection surface of the first mircobump and the connection surface of the second microbump are removed.

11. The substrate processing method of claim 1, wherein, in (c), the insulating film is formed on the first surface, the second surface, the first mircobump and the second microbump by performing a cycle at least once, and
wherein the cycle comprises:
(c-1) forming an insulating layer on the first surface, the second surface, the first mircobump and the second microbump by supplying a source gas to the first surface, the second surface, the first mircobump and the second microbump; and
(c-2) exposing the insulating layer to a reducing atmosphere.

12. The substrate processing method of claim 1, wherein the insulating film is formed to prevent a difference in a wettability between the second surface of the semiconductor chip and a surface of the second microbump, or between the first surface of the substrate and a surface of the first microbump.

13. The substrate processing method of claim 6, wherein (g) is performed in a state where the insulating film is exposed on the substrate, in a state where a conductive film formed on the insulating film is exposed, in a state where an organic insulating film formed on the conductive film and containing an organic substance is exposed, or in a state where an organic insulating film formed on the insulating film and containing the organic substance is exposed.

14. The substrate processing method of claim 6, wherein (g) is performed in a state where the insulating film is formed on the substrate, in a state where a conductive film is formed on the insulating film, in a state where an organic insulating film containing an organic substance is formed on the conductive film, or in a state where the organic insulating film is formed on the insulating film.

15. The substrate processing method of claim 1, wherein the insulating film comprises an inorganic insulating film.

16. A substrate processing method comprising:
performing at least one among:
(a) forming an insulating film on a first surface of a substrate and a first microbump formed on the first surface, wherein the first surface faces a semiconductor chip when the substrate and the semiconductor chip are bonded together; and
(b) forming the insulating film on a second surface of the semiconductor chip and a second microbump formed on the second surface, wherein the second surface faces the substrate when the substrate and the semiconductor chip are bonded together.

17. The substrate processing method of claim 16, wherein, in (a) or (b), the insulating film is formed on the first surface and the first mircobump, or on the second surface and the second microbump by performing a cycle at least once, and
wherein the cycle comprises:
(c-1) forming an insulating layer on the first surface and the first mircobump by supplying a source gas to the first surface and the first mircobump, or on the second surface and the second microbump by supplying the source gas to the second surface and the second microbump; and
(c-2) exposing the insulating layer to a reducing atmosphere.

18. A method of manufacturing a semiconductor device, comprising:
the method of claim 16.

19. A processing apparatus comprising:
a substrate support configured to support a substrate provided with a first surface and a first microbump formed on the first surface, or configured to support a semiconductor chip provided with a second surface and a second microbump formed on the second surface, wherein the first surface faces the semiconductor chip and the second surface faces the substrate when the substrate and the semiconductor chip are bonded together;
a gas supplier configured to supply a source gas to the substrate support; and
a controller configured to be capable of controlling the gas supplier to perform at least one among:
(a) forming an insulating film on the first surface and the first microbump formed on the first surface; and
(b) forming the insulating film on the second surface and the second microbump formed on the second surface.

20. A non-transitory computer-readable recording medium storing a program that causes a processing apparatus, by a computer. to perform
a process comprising the method of claim 16.
